(19) United States
(12) Patent Application Publication
(10) Pub. No.: US 2010/0051896 A1
(43) Pub. Date: Mar. 4, 2010

(54) VARIABLE RESISTANCE MEMORY DEVICE USING A CHANNEL-SHAPED VARIABLE RESISTANCE PATTERN

(75) Inventors: Jeonghee Park, Gyeonggi-do (KR); Yongho Ha, Gyeonggi-do (KR); Dohyung Kim, Gyeonggi-do (KR); Joonsang Park, Seoul (KR); Hyeyoung Park, Gyeonggi-do (KR); Hyun-Suk Kwon, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/549,887

(22) Filed: Aug. 28, 2009

(30) Foreign Application Priority Data
Sep. 2, 2008 (KR) 10-2008-0086413
Jun. 8, 2009 (KR) 10-2009-0050491

(51) Int. Cl. H01L 47/00

(52) U.S. Cl. 257/4; 257/E47.001

(57) ABSTRACT

A variable resistance memory device includes a substrate and a plurality of spaced apart lower electrodes on the substrate. The device further includes a variable resistance material pattern comprising two vertically opposed wall members connected by a bottom member disposed on and electrically connected to at least one of the plurality of lower electrodes and an upper electrode on the variable resistance material pattern. An area of contact of the variable resistance material pattern with the at least one lower electrode may be rectangular, circular, ring-shaped, or arc-shaped. Fabrication methods are also described.

### CROSS-REFERENCE TO RELATED APPLICATIONS

This U.S. non-provisional patent application claims priority under 35 U.S.C. §119 of Korean Patent Applications No. 10-2008-0086413, filed on Sep. 2, 2008 and No. 10-2009-0050491, filed on Jun. 8, 2009, the entire contents of which are herein incorporated by reference in their entirety.

### BACKGROUND

The present invention relates generally to semiconductor memory devices and methods of manufacturing the same, and more particularly, to variable resistance memory devices and methods of manufacturing the same.

Conventionally, semiconductor memory devices may be classified into volatile memory devices, such as dynamic random access memory (DRAM) and static random access memory (SRAM) devices, which can not maintain data when a power supply is interrupted and nonvolatile random access memory (DRAM), such as programmable read only memory (PROM), erasable programmable read only memory (EPROM), electrically erasable programmable read only memory (EEPROM) and flash memory devices, which can maintain data even when a power supply is interrupted.

In response to a demand for higher performance and lower power consumption, next generation semiconductor memory devices, such as ferroelectric random access memory (FRAM), magnetic random access memory (MRAM) and phase-change random access memory (PRAM), have been developed. Materials used for data storage in such next generation semiconductor memory devices have different resistance for different data and maintain the resistance even if a supply of a current or a voltage is interrupted.

Phase-change memory device (PRAM) using a phase-change material may provide high operation speed and a structure which advantageous to a high level of integration. Thus, phase-change memory (PRAM) has become a subject of recent product development.

### SUMMARY

Some embodiments of the present invention provide a variable resistance memory device including a substrate and a plurality of spaced apart lower electrodes on the substrate. The device further includes a variable resistance material pattern having a channel shape comprising two vertically opposed wall members connected by a bottom member disposed on and electrically connected to at least one of the plurality of lower electrodes. An upper electrode is disposed on the variable resistance material pattern. The device may further include a heat loss preventing layer conforming to an inner surface of the variable resistance material pattern.

A width of the bottom member may be less than a distance between upper edges of the wall members. A thickness of the bottom member may be greater then or equal to a thickness of the wall members. An area of contact of the variable resistance material pattern with the at least one lower electrode may be rectangular, circular, ring-shaped, or arc-shaped. The variable resistance material pattern may overlap a sidewall surface of the at least one lower electrode. The lower electrodes may be disposed in an insulation layer, and the variable resistance material pattern may protrude into the insulating layer to contact the at least one lower electrode. The upper electrode may contact upper surfaces of the wall members of the variable resistance material pattern.

Further embodiments of the present invention provide methods of manufacturing a variable resistance memory device. A plurality of spaced apart lower electrodes is formed on a semiconductor substrate. An interlayer insulating layer is formed on the plurality of lower electrodes. A trench is formed in the interlayer insulating layer, exposing the plurality of lower electrodes. A variable resistance material pattern is formed on an inner surface of the trench. An upper electrode is formed on the variable resistance material pattern.

Forming the variable resistance material pattern may include forming a variable resistance material layer on the interlayer insulating layer and in the trench, forming an insulating layer on the variable resistance material layer and removing portions of the variable resistance material layer and the insulating layer to expose the interlayer insulating layer and thereby form the variable resistance material pattern. A heat loss preventing layer may be formed on the variable resistance material pattern.

### BRIEF DESCRIPTION OF THE FIGURES

The accompanying figures are included to provide a further understanding of the present invention, and are incorporated in and constitute a part of this specification. The drawings illustrate some embodiments of the present invention and, together with the description, serve to explain principles of the present invention. In the figures:

FIG. 1 is a schematic diagram illustrating a variable resistance memory device according to some embodiments of the present invention;

FIG. 2 is a graph illustrating a characteristic of a variable resistance memory device according to some embodiments of the present invention;

FIG. 3A is a top plan view of a variable resistance memory device according to some embodiments of the present invention;

FIG. 3B is a top plan view of a unit memory cell region of FIG. 3A;

FIGS. 4A and 4B are cross sectional views of a variable resistance memory device according to some embodiments of the present invention, the cross sectional views being taken along the lines A-A′ and B-B′, respectively, of FIG. 3A;

FIG. 4C is a view of variable resistance material pattern of a variable resistance memory device according to embodiments of the present invention;

FIGS. 5A and 5B are cross sectional views of a variable resistance memory device according to some embodiments of the present invention, the cross sectional views being taken along the lines A-A′ and B-B′, respectively, of FIG. 3;

FIGS. 6A and 6B are cross sectional views of a variable resistance memory device according to some embodiments of the present invention, the cross sectional views being taken along the lines A-A′ and B-B′, respectively, of FIG. 3A;

FIG. 7A is a top plan view of a variable resistance memory device according to some embodiments of the present invention;

FIG. 7B is a top plan view of a unit memory cell region of FIG. 7A;

FIGS. 8A and 8B are cross sectional views of a variable resistance memory device according to some embodiments of the present invention, the cross sectional views being taken along the lines A-A′ and B-B′, respectively, of FIG. 7A;

FIG. 9A is a top plan view of a variable resistance memory device according to some embodiments of the present invention;

FIG. 9B is a top plan view of a unit memory cell region of FIG. 9A;

FIGS. 10A and 10B are cross sectional views of a variable resistance memory device according to some embodiments of the present invention, the cross sectional views being taken along the lines A-A′ and B-B′, respectively, of FIG. 9A;

FIGS. 11A and 11B are cross sectional views of a variable resistance memory device according to some embodiments of the present invention, the cross sectional views being taken along the line A-A′ of FIG. 9A;

FIG. 12A is a top plan view of a variable resistance memory device according some embodiments of the present invention;

FIG. 12B is a top plan view of a unit memory cell region of FIG. 12A;

FIGS. 13A through 19A are cross sectional views illustrating operations for manufacturing a variable resistance memory device according to some embodiments of the present invention, the cross sectional views being taken along the line A-A′ of FIG. 3A;

FIGS. 13B through 19B are cross sectional views illustrating operations for manufacturing a variable resistance memory device according to some embodiments of the present invention, the cross sectional views being taken along the line B-B′ of FIG. 3A; and

FIG. 20 is a block diagram of a memory system illustrating an application of a variable resistance memory device according to some embodiments of the present invention.

### DETAILED DESCRIPTION

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

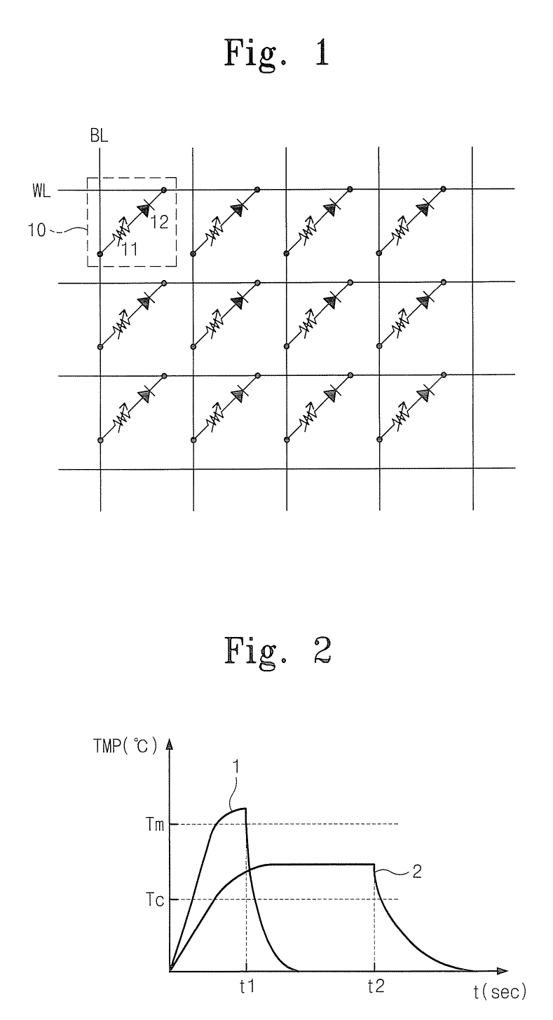

FIG. 1 is a circuit view of a cell array of a variable resistance memory device according to some embodiments of the present invention.

Referring to FIG. 1, a plurality of memory cells 10 is arranged in matrix shape. Each of the memory cells 10 includes a variable resistance memory device 11 and a selection device 12. The variable resistance memory device 11 is disposed between the selection device 12 and a bit line BL and connected to the selection device 12 and the bit line BL. The selection device 12 is disposed between the variable resistance memory device 11 and a word line WL and connected to the variable resistance memory device 11 and the word line WL.

The variable resistance memory device 11 may, for example, include a phase-change material, a ferroelectric material or a magnetic material. A state of the variable resistance memory device 11 may be determined by the amount of a current flowing through the bit line BL.

The amount of a current flowing to the variable resistance memory device 11 through the selection device 12 is controlled by a voltage of the word line WL. A diode is shown as the selection device 12 in the view but a MOS transistor or a bipolar transistor may be used as the selection device 12.

Hereinafter, variable resistance memory devices including memory cells adopting a phase change material will be described in embodiments of the present invention. The present invention is not limited to phase change material devices, and can be applied, for example, to resistance random access memory (RRAM), ferroelectric random access memory (FRAM) and magnetic random access memory (MRAM) devices.

In some embodiments of the present invention, a resistance of a phase change material of the variable resistance memory device 11 is changed according to a temperature. For example, a phase change material may have an amorphous state having a relatively high resistance and a crystalline state having a relatively low resistance according to a temperature and a cooling time. Joule heat is generated from the variable resistance memory device 11 according to the amount of a current supplied through a lower electrode to heat a phase change material. The Joule heat is generated in proportion to a resistivity of a phase change material and a supply time of a current.

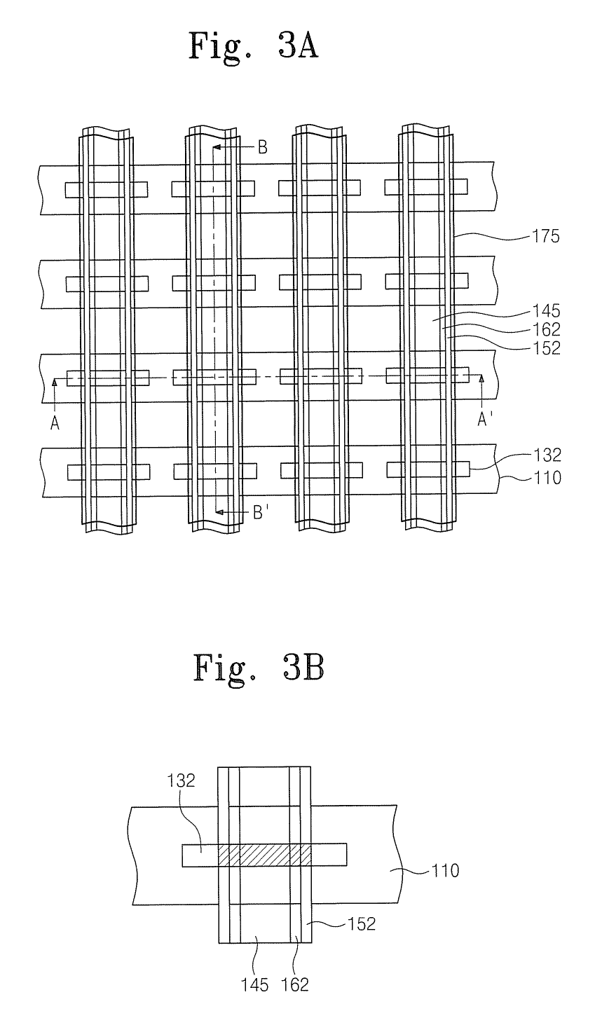

FIG. 2 is a graph illustrating a characteristic of a variable resistance memory device according to some embodiments of the present invention.

Referring to FIG. 2, if quenching a phase change material after heating it for a time of t1 at a temperature higher than a melting temperature Tm by a supply of a current, the phase change material may take on an amorphous state having an irregular crystalline structure. An amorphous state may be defined as a reset state or a state that corresponds to a data “1”. If cooling a phase change material slowly after heating it for a time of t2 longer than t1 at a temperature higher than a crystal temperature Tc and lower than a melting temperature Tm by a supply of a current, the phase change material may take on a crystalline state. A crystalline state may be defined as a set state or a state corresponding to data “0”. A current may be supplied to a phase change material and a resistance of the phase change material measured to read data.

A heating temperature of a phase change material is proportional to the amount of a current. As the amount of a current required to program a cell is increased, it may become difficult to highly integrate cells. A change to an amorphous state (a reset state) typically requires more current than a change to a crystalline state (a set state), which may affect power consumption. Thus, in order to reduce power consumption, it is generally desirable that heating a phase change material to change to an amorphous state or a crystalline state use a small amount of a current. In particular, it is desirable that the current needed to change to an amorphous state (i.e., a reset current) be limited to allow a higher degree of integration.

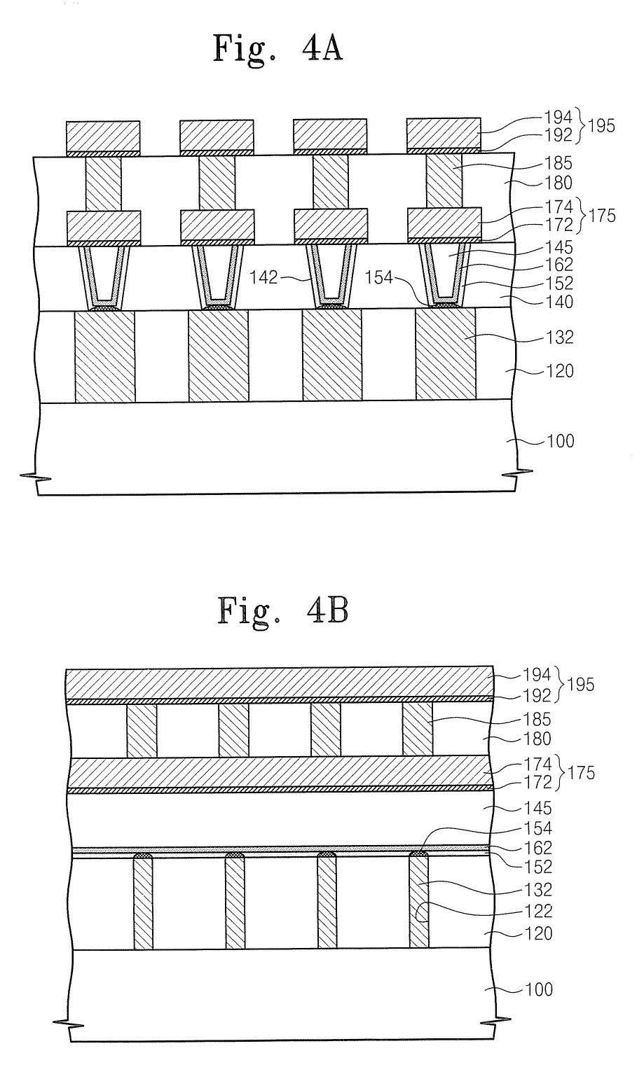

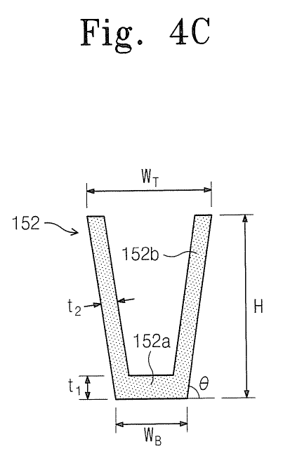

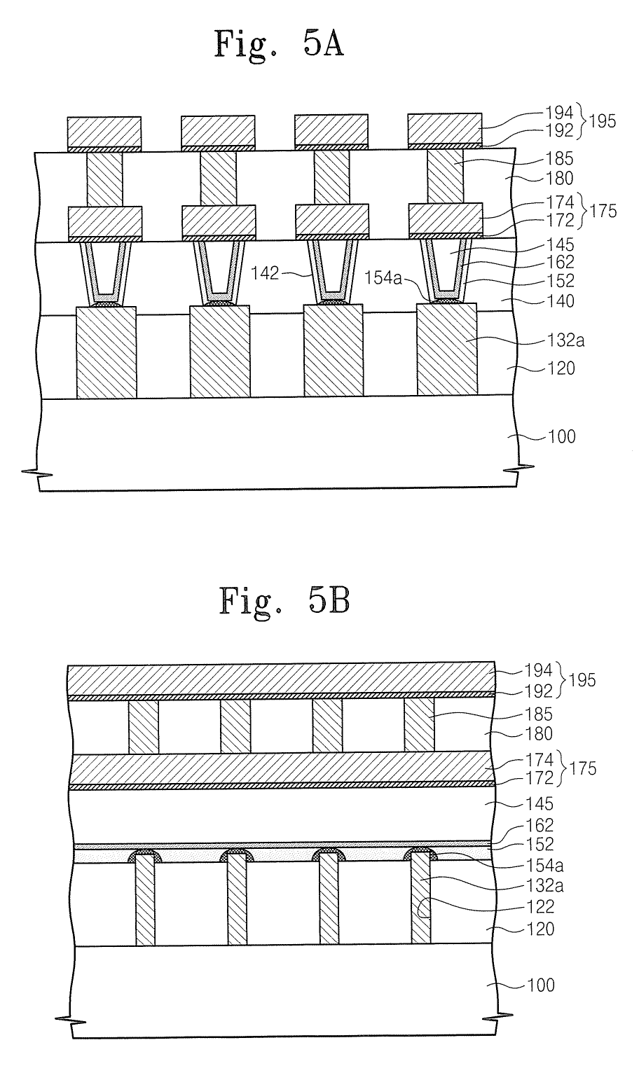

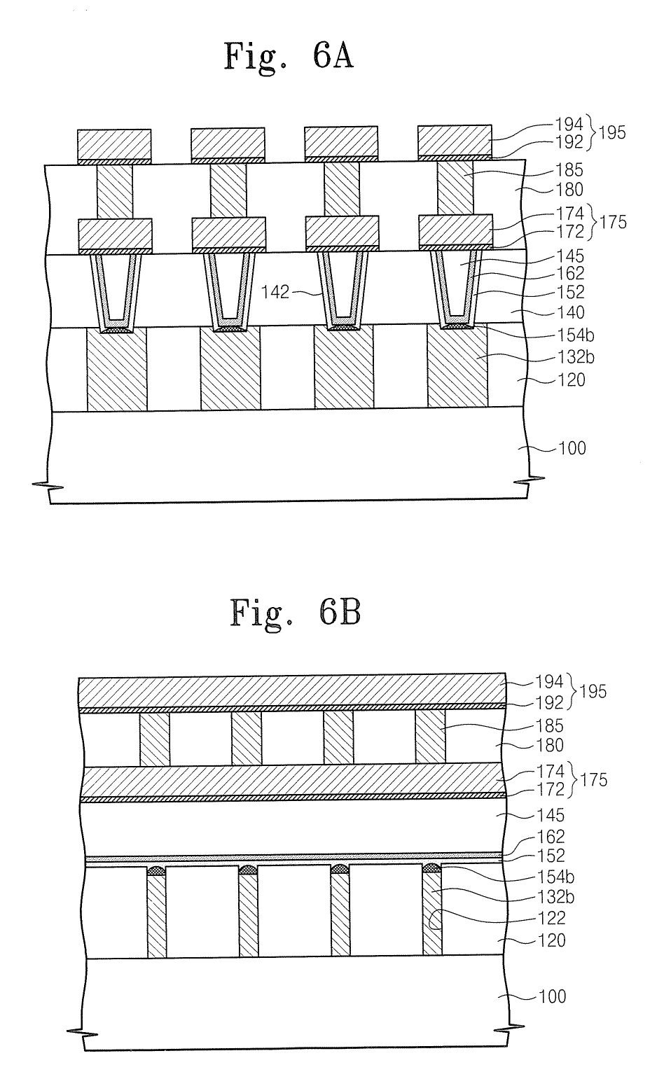

FIG. 3A is a top plan view of a variable resistance memory device according to some embodiments of the present invention. FIG. 3B is a top plan view of a unit memory cell region of FIG. 3A. FIGS. 4A and 4B are cross sectional views of a variable resistance memory device according to some embodiments of the present invention, the cross sectional views being taken along the lines A-A′ and B-B′, respectively, of FIG. 3A. FIG. 4C is a view of a variable resistance material pattern of a variable resistance memory device according to some embodiments of the present invention.

Referring to FIGS. 3A, 3B, 4A and 4B, a first interlayer insulating layer 120 including a lower electrode 132 is disposed on a semiconductor substrate 100. The semiconductor substrate 100 includes word lines 110 extending in a first direction. The word lines 110 may be doped with an impurity. The semiconductor substrate 100 may include a plurality of selection circuits (not shown), such as diodes or MOS transistors, and the plurality of selection circuits may be electrically connected to lower electrodes 132.

A first interlayer insulating layer 120 and lower electrodes 132 therein having a straight (or line) shape are disposed on the semiconductor substrate 100. The lower electrodes 132 are spaced a predetermined distance apart from each other on the word lines 110. Each of the lower electrodes 132 have a long axis and a short axis, and a width of the lower electrodes along the short axes is smaller than a width of the word lines 110. The lower electrodes 132 may have a structure extending in the first direction or a structure extending in a second direction perpendicular to the first direction.

A second interlayer insulating layer 140 is formed on the lower electrodes, and trenches 142 exposing a portion of or an entire portion of top surfaces of the lower electrodes 132 are formed in the second interlayer insulating layer 140. The trenches 142 expose the lower electrodes 132. The trenches 142 may extend in a direction to be parallel to the word lines 110 or may extend in a direction perpendicular to the word lines 110. The trenches 142 may have a gradually narrowing width from top to bottom thereof.

Variable resistance material patterns 152 formed on inner surfaces of in the trenches 142 have a generally U-shaped cross section. The variable resistance material patterns 152 are conformally formed along an inner wall of the trench 142. The variable resistance material patterns 152 may extend in a direction perpendicular to a major direction of the lower electrodes. Therefore, the variable resistance material pattern 152 may extend in the first direction or may extend in a second direction perpendicular to the first direction.

As depicted in FIG. 4C, the variable resistance material pattern 152 is channel-shaped that has a generally U-shaped cross section, and includes two vertically opposed wall members 152b and one bottom member 152a connecting the wall members 152b at bases thereof. A distance W_{T} between upper edges of the wall members 152b is greater than a width W_{B} of the bottom member 152a, and the wall members 152 are generally inclined with respect to top surfaces of the lower electrodes. In some embodiments, for example, the distance W_{T} between the upper edges of the wall members 152b and the width W_{B} of the bottom member 152a may be about 5 nm to 100 nm, for example, about 5 nm to 40 nm.

The width W_{B} of the lower portion of the variable resistance material pattern 152 may be equal to or less than a width of a major axis of the lower electrode 132. If the width W_{B} of a lower portion of the variable resistance material pattern 152 is less than a width of a major axis of the lower electrode 132, an area that the variable resistance material pattern 152 and the lower electrode 132 are in contact with each other may be decreased to reduce a reset current. A hatching portion in FIG. 3B represents a contact portion (i.e., a variable resistance region) between the variable resistance material pattern 152 and the lower electrode 132.

Also, an area where the bottom member 152a of the variable resistance material pattern 152 and the lower electrode 132 are in contact with each other may be smaller than an area where a wall member 152b of the variable resistance material pattern 152 and an upper electrode 175 are in contact with each other. Therefore, heat may be concentrated on an interface where the variable resistance material pattern 152 and the lower electrode 132 are in contact with each other. The wall member 152b of the variable resistance material pattern 152 may have a gradient 0 of about 60 degrees to 90 degrees with respect to the upper surface of the lower electrode 132, in some embodiments, a gradient 0 of about 75 degrees to about 85 degrees. The variable resistance material pattern 152 may have a thickness t1 of the bottom member 152a equal to or greater than a width t2 of the wall member 152b. A thickness t1 of the bottom member 152a may be, for example, about ⅛ to ½ of a height H of the variable resistance material pattern 152, in some embodiments, about ¼ of the height H of the variable resistance material pattern 152. For example, the thickness t1 of the bottom member and a thickness t2 of a wall member of the variable resistance material pattern 152 may be about 1 to 50 nm. Also, the variable resistance material pattern 152 may have an aspect ratio of about 2:1 to about 4:1.

Since the variable resistance material pattern 152 has a generally U-shaped cross section, a bottom member 152a which is in contact with the lower electrodes 132 may have a relatively small thickness. Thus, when heating the variable resistance material pattern 152 through the lower electrode 132, a volume of a variable resistance region 154 can be reduced. In particular, a variable resistance material around a region that the variable resistance material pattern 152 and the lower electrode 132 are in contact with each other may be limited to a specific thickness to limit the volume of the variable resistance region 154. An area that the variable resistance material pattern 152 and the lower electrode 132 are in contact with each other may be relatively small, so that a volume of the variable resistance region 154 may be relatively small. Since the volume of the variable resistance region 154 can be limited, the current used when programming data can be kept relatively small. As a result, power consumption can be reduced. When a variable resistance memory device operates, a shape and a volume of the variable resistance region 154 may be changed by a voltage condition.

A heat loss preventing layer 162 is formed on a surface of the variable resistance material pattern 152. The heat loss preventing layer 162 may be formed of an insulating material to prevent a loss of a heat generated when heating the phase change material to perform a phase change. Because the phase change material can be heated to a melting point using a relatively small amount of a current, power consumption of a variable resistance memory device can limited.

The heat loss preventing layer 162 is formed on the variable resistance region 154 where phase change material is changed through the lower electrode 132. That is, the heat loss preventing layer 162 may cover a bottom member 152a of the variable resistance material pattern 152 may extend along an inner wall of the variable resistance material pattern.

Since the heat loss preventing layer 162 is formed on an inner wall of the variable resistance material pattern 152, a resistance of a phase change material can be changed using a relatively small amount of current. The heat loss preventing layer 162 may be formed, for example, from a material selected from a group including of SiN, PE-SiN, SiON, C, ALD-AIN, GeN, Al₂O₃, MgO, SiO₂, CaO, Y₂O₃, TiO₂, Cr₂O₃, FeO, CoO, ZrO and CuO₂.

An insulating layer pattern 145 filling a gap between wall members 152b of the variable resistance material pattern 152 is disposed on the heat loss preventing layer 162. For example, the insulating layer pattern 145 may be an oxide layer. Top surfaces of the variable resistance material pattern 152, the heat loss preventing layer 162, the insulating layer pattern 145 and the second interlayer insulating layer 140 may be coplanar. The variable resistance 152 may include two lines on upper portion of one word line 110.

Even though the heat loss preventing layer 162 and the insulating layer pattern 145 are in the trench 142 including the variable resistance material pattern 152, only one of the heat loss preventing layer 162 and the insulating layer pattern 145 may be buried in the trench 142. That is, an inner surface of the variable resistance material pattern 152 having a cross section of a U shape may be in contact with insulating layer pattern 145.

An upper electrode 175 is disposed on a top surface of the variable resistance material pattern 152. Specifically, the upper electrode 175 covers the variable resistance material pattern 152, the heat loss preventing layer 162 and the insulating layer pattern 145. The upper electrode 175 is in contact with top surfaces of wall members 152b of the variable resistance material pattern 152. Alternatively, the upper electrode 175 may be in contact with just one of the two wall members 152b of the variable resistance material pattern 152. The upper electrode 175 may have a plate shape substantially corresponding to the shape of the lower electrode 132 or may have a line shape perpendicular to the underlying word line 110. The upper electrode 175 may be used as a bit line (BL) contact.

Bit lines 195 crossing the word lines 110 are disposed on the upper electrodes 175. The bit lines 195 may be electrically connected to the upper electrodes 175 through contact plugs 185. The upper electrode 175 and the bit line 195 may each have a structure wherein the barrier layer 172, 192 and the conductive layer 174,194 are stacked. The contact plug 185 may also have a structure wherein the barrier layer and the conductive layer are stacked.

The upper electrode 175 on the variable resistance material pattern 152 may be omitted. That is, the contact plugs 185 connected to the bit line 195 may be directly in contact with a top surface of the variable resistance material pattern 152.

When a current flows to the variable resistance material pattern 152 through the lower electrode 132 in the variable resistance memory device, a phase change may occur at a contact surface of the lower electrode 132 and the variable resistance material pattern 152. Since the variable resistance material pattern 152 has a U-shaped cross section, a thickness of a bottom member 152a which is in contact with the lower electrode 132 may be relatively small. Therefore, even if a current increases, the volume of the variable resistance region 154 may be limited. In particular, because a volume of the variable resistance region 154 can be limited, the amount of a current required to change a state of the variable resistance material pattern 152 can be relatively small.

Also, the heat loss preventing layer 162 is disposed on a bottom member 152a of the variable resistance material pattern 152 which is in contact with the lower electrode 132 limits heat dissipation to the vicinity of the variable resistance material pattern 152 when the variable resistance material pattern 152 is heated. In addition, because the variable resistance material pattern 152 extends in one direction to be in contact with a plurality of lower electrodes 132, an alignment margin between the variable resistance material pattern 152 and the upper electrode 172 or between the variable resistance material pattern 152 and the bit line 195 can be obtained.

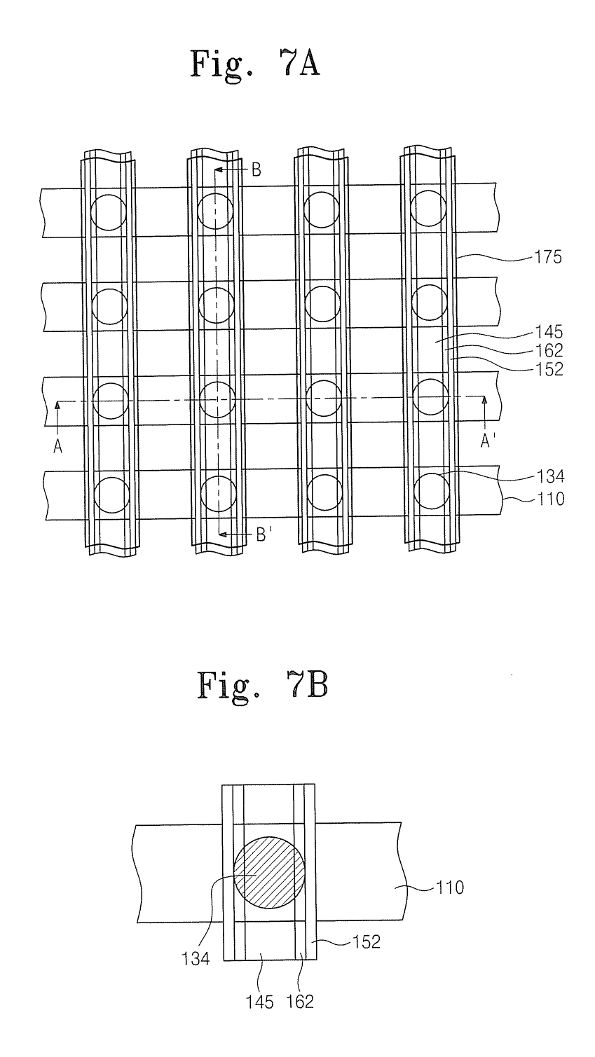

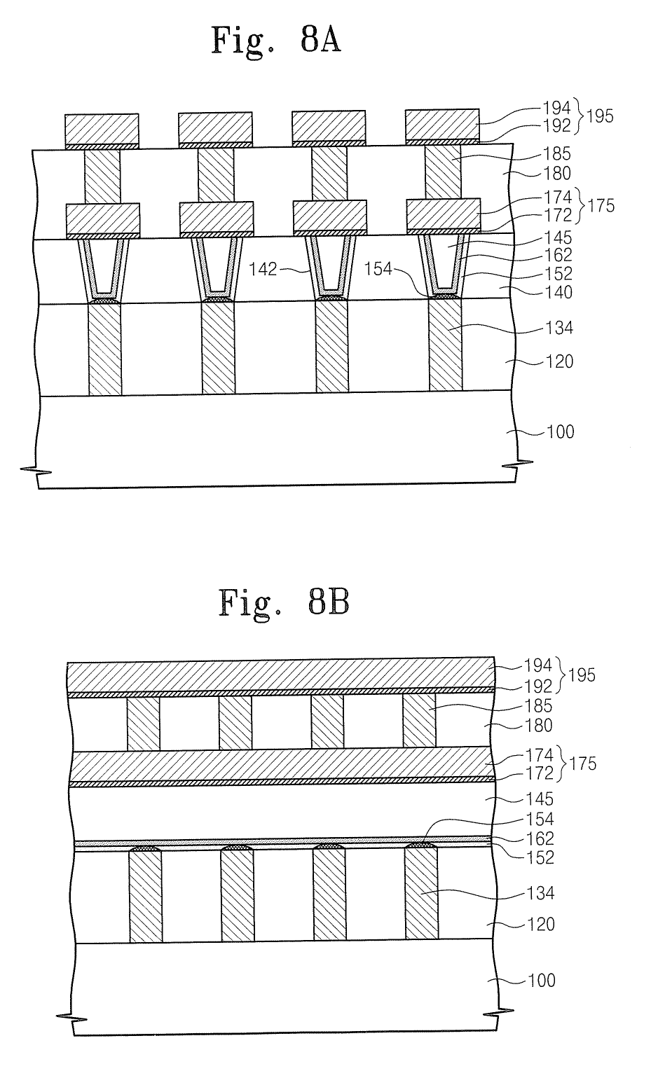

Referring to FIGS. 5A through 6B, a variable resistance memory device which according to some embodiments of the present invention is described. Like reference numerals refer to common features shared with the previously described embodiments, and further detailed description of these common features is omitted in light of the foregoing description.

FIGS. 5A and 5B are cross sectional views of a variable resistance memory device according to some embodiments of the present invention, the cross sectional views being taken along the lines A-A′ and B-B′ of FIG. 3, respectively.

Referring to FIGS. 5A and 5B, a lower electrode 132a may protrude from a top surface of the first interlayer insulating layer 120. A top surface of the lower electrode 132a may be higher than the top surface of the first interlayer insulating layer 120. The variable resistance material pattern 152 may overlap a sidewall of the protruding lower electrode 132a. The variable resistance material pattern 152 may have a rectangular area of contact with the lower electrodes 132a, and a thickness of the variable resistance material pattern on the lower electrode 132a may be different from a thickness of the variable resistance material pattern on the first interlayer insulating layer 120. Thus, when the variable resistance memory device operates, a variable resistance region 154A may be formed around a portion of the lower electrode 132a.

FIGS. 6A and 6B are cross sectional views of a variable resistance memory device according to further embodiments of the present invention. The cross sectional views are taken along the lines A-A′ and B-B′, respectively, of FIG. 3A. Referring to FIGS. 6A and 6B, a top surface of a lower electrode 132b may be recessed from a top surface of the first interlayer insulating layer 120. Thus, a thickness of the variable resistance material pattern 152 on the lower electrode 132b may be different from a thickness of the variable resistance material pattern 152 on the first insulating layer 120. A lower portion of the variable resistance material pattern 152 may protrude into a cavity above the lower electrode 132b, such that a bottom surface of the variable resistance material pattern 152 may be lower than a top surface of the lower electrode 132b. Thus, when the variable resistance memory device operates, the variable resistance region 154B may be formed at the lower portion of the variable resistance material pattern 152 that is inserted into cavity above the lower electrode 132b.

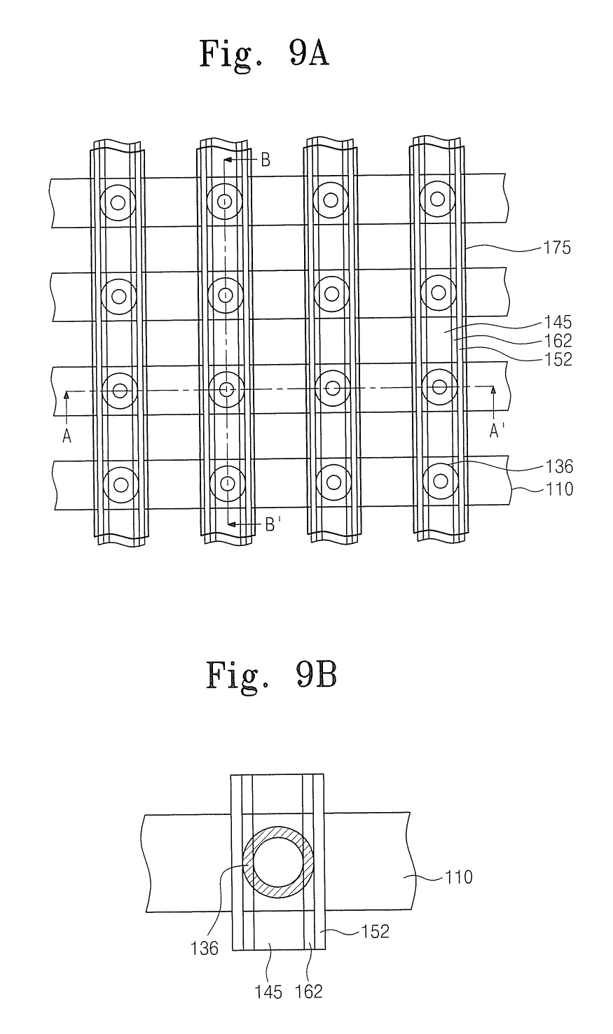

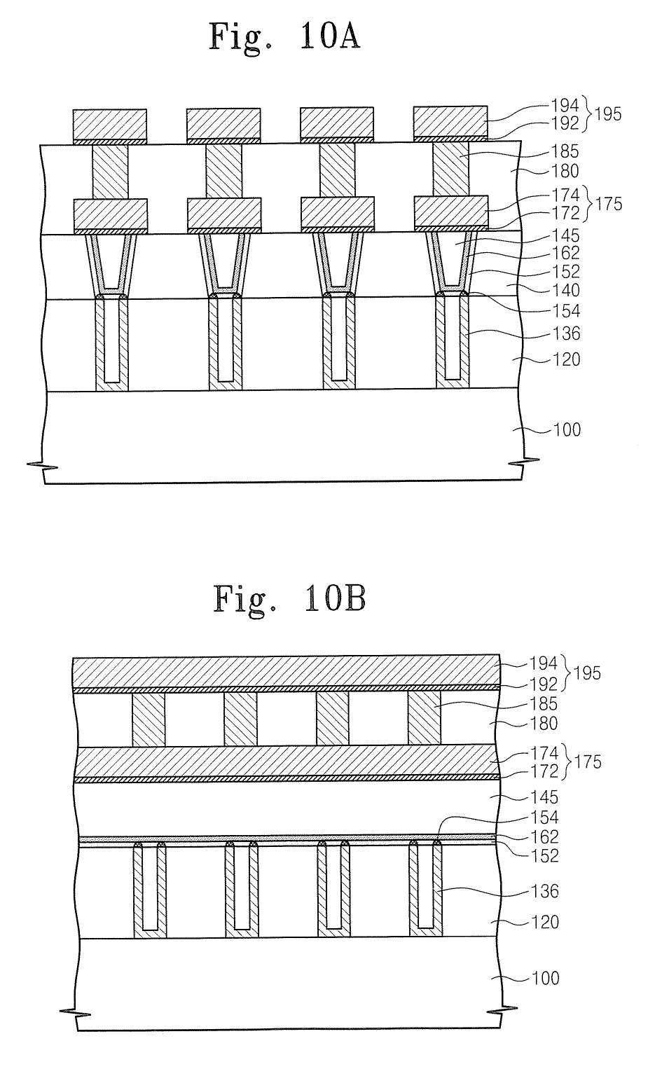

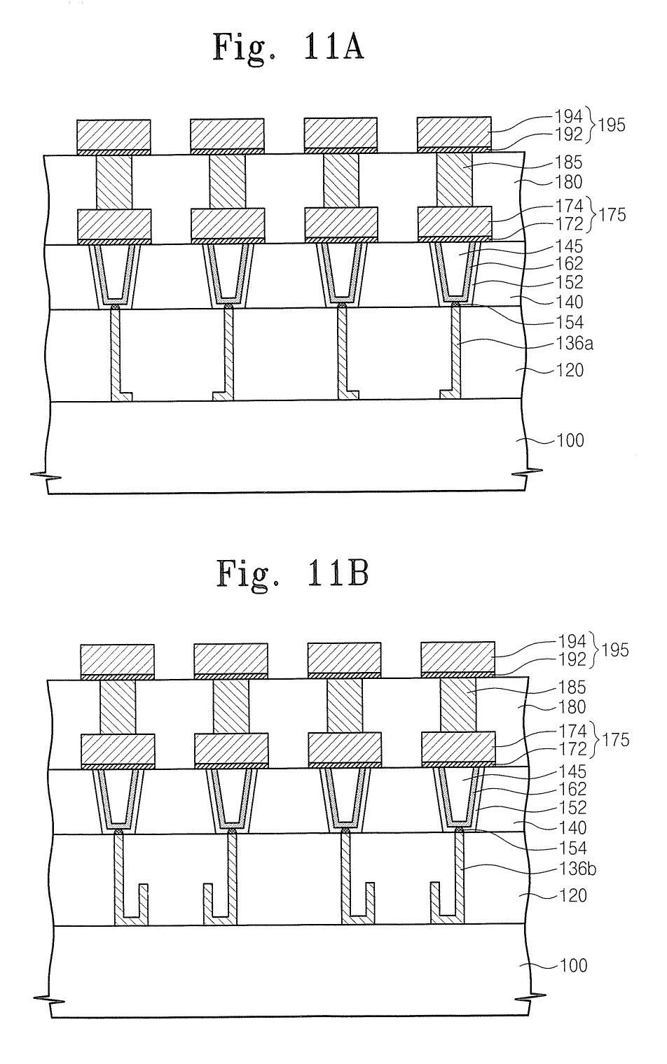

Referring to FIGS. 7A, 7B, 8A and 8B, a variable resistance memory device according to further embodiments of the present invention will be described. Like numbers indicate features in common with the previously described embodiments, and further detailed description of such features will be omitted in light of the foregoing description.

FIG. 7A is a top plan view of a variable resistance memory device according to further embodiments of the present invention. FIG. 7B is a top plan view of a unit memory cell region of FIG. 7A. FIGS. 8A and 8B are cross sectional views of a variable resistance memory device according to some embodiments of the present invention, the cross sectional views being taken along the lines A-A′ and B-B′, respectively, of FIG. 7A.

Referring to FIGS. 7A, 7B, 8A and 8B, a first interlayer insulating layer 120 is disposed on a semiconductor substrate 100 including a word line 110 and a selection device (not shown). The first interlayer insulating layer 120 has lower electrodes 134 therein having a pillar shape of a square or circle cross-section. The lower electrodes 134 may be arranged as a matrix on upper portions of the word lines 110. Spacers (not shown) may be formed around the lower electrodes 134 such that a diameter of the lower electrodes 134 may be reduced. The lower electrodes 134 may protrude or be recessed with respect to the first interlayer insulating layer 120, along lines described above with reference to FIGS. 5A through 6B.

Variable resistance patterns 152 having a generally U-shaped cross section and extending in one direction is disposed on the lower electrodes 134. As depicted in FIG. 4C, the variable resistance material patterns 152 include a bottom member 152a and wall members 152b. A width of the bottom member 152a may be smaller than a distance between upper edges of the wall members 152b. A bottom member 152a of a variable resistance material pattern 152 may be in contact with some or all of a top surface of a lower electrode 134, e.g., For example, a width of a bottom member 152a of the variable resistance material pattern 152 may be less than, equal to or greater than a width of the lower electrode 134. The hatching in FIG. 7B represents circular contact areas between the lower electrodes 134 and the variable resistance material patterns 152.

A heat loss preventing layer 162 is formed on an inner wall of the variable resistance material pattern 152. An insulating layer 145 is disposed between wall members of the variable resistance material pattern 152, on the heat loss preventing layer 162.

An upper electrode 175 is disposed on a top surface of the variable resistance 152. The upper electrode 175 may have a plate shape similar to the lower electrode 134 or may have a line shape extending perpendicular to the underlying word line 110. In the illustrated example, the upper electrode 175 may be used as a bit line (BL) contact. Bit lines 195 crossing the word lines 110 are disposed on the upper electrodes 175. The bit lines 195 may be electrically connected to the upper electrodes 175 through contact plugs 185.

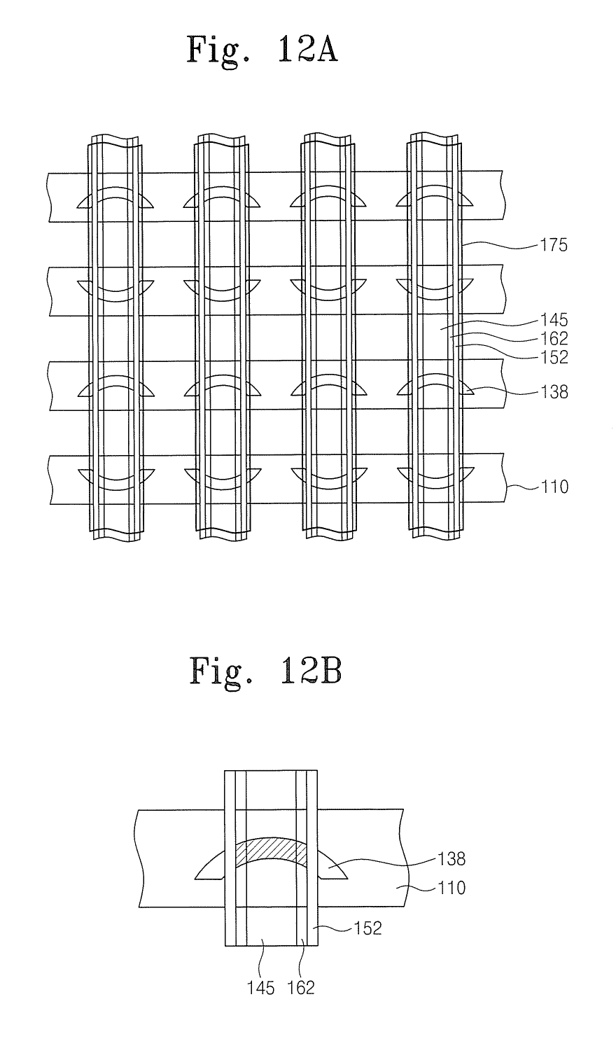

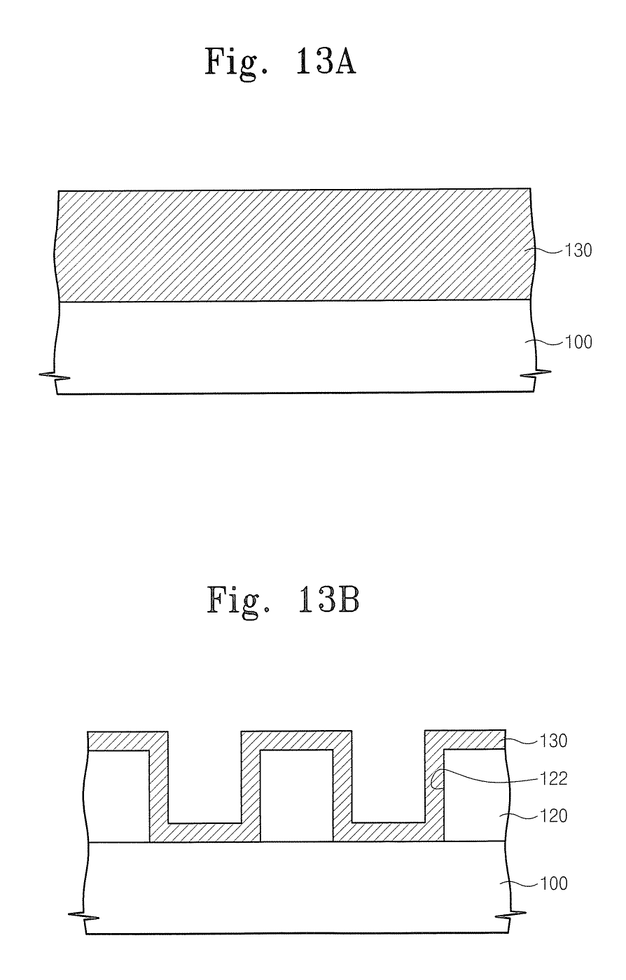

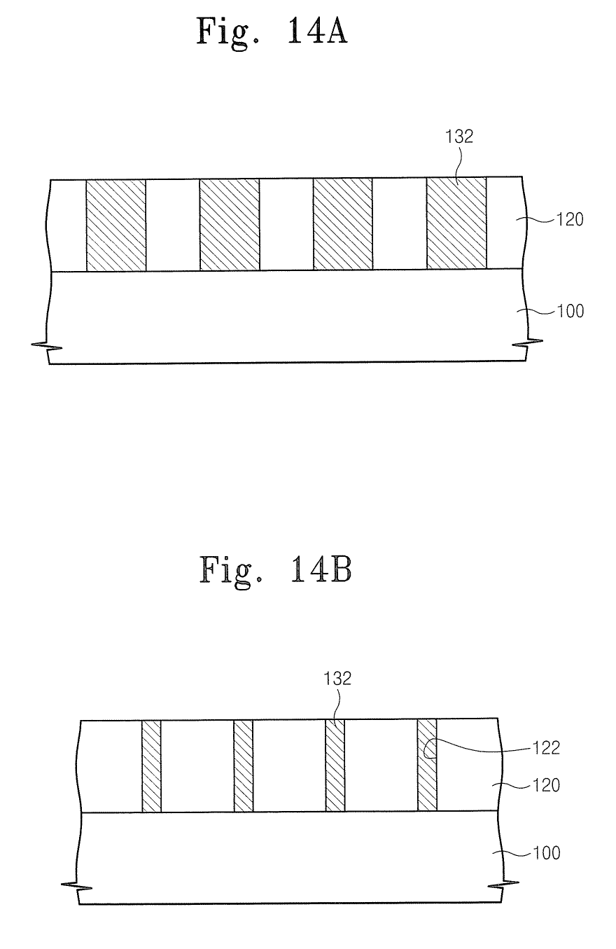

Referring to FIGS. 9A, 9B, 10A and 10B, a variable resistance memory device according to additional embodiments of the present invention will be described. Like reference numerals refer to common features shared with the previously described embodiments, and further detailed description of these common features is omitted in light of the foregoing description.

Referring to FIGS. 9A, 9B, 10A and 10B, a first interlayer insulating layer 120 is disposed on a semiconductor substrate 100 including word lines 110 and selection devices (not shown). Hollowed-out cylindrical lower electrodes 132 are formed in the first interlayer insulating layer 120. The lower electrodes 136 are arranged in a matrix on upper portions of the word lines 110.

Variable resistance patterns 152 have a U-shaped cross section and extend along one direction, and are disposed on the lower electrodes 136. As depicted in FIG. 4C, the variable resistance material patterns 152 each include a bottom member 152a and wall members 152b. A width of the bottom member 152a may be smaller than a distance between upper edges of the wall members 152b. The bottom member 152a may be in contact with some or all of a top surface of the lower electrode 136. For example, a width of a bottom member 152a may be less than, equal to or greater than a width of the lower electrode 136. The hatching shown in FIG. 9B represents contact regions between the lower electrodes 136 and the variable resistance material patterns 152. Because the top surfaces of the lower electrodes 136 are ring shaped, an area of contact with the variable resistance material pattern 152 may be a relatively small ring-shaped area. Thus, a volume of the variable resistance region 154 can be reduced, and the amount of a current used when data is programmed can be reduced, thereby reducing power consumption. The lower electrode 136 may, along lines described above with reference to FIGS. 5A through 6B, protrude from or be recessed with respect to the first interlayer insulating layer 120.

A heat loss preventing layer 162 is formed on an inner wall of the variable resistance material patterns 152. An insulating layer 145 is disposed between portions of the variable resistance material pattern 152, on the heat loss preventing layer 162.

An upper electrode 175 is disposed on a top surface of the variable resistance 152 having a U shape. The upper electrode 175 may have a plate shape or may have a line shape perpendicular to the underlying word line 110. As shown, the upper electrode 175 may be used as a bit line (BL) contact. Bit lines 195 crossing the word lines 110 are disposed on the upper electrodes 175. The bit lines 195 may be electrically connected to the upper electrodes 175 through contact plugs 185.

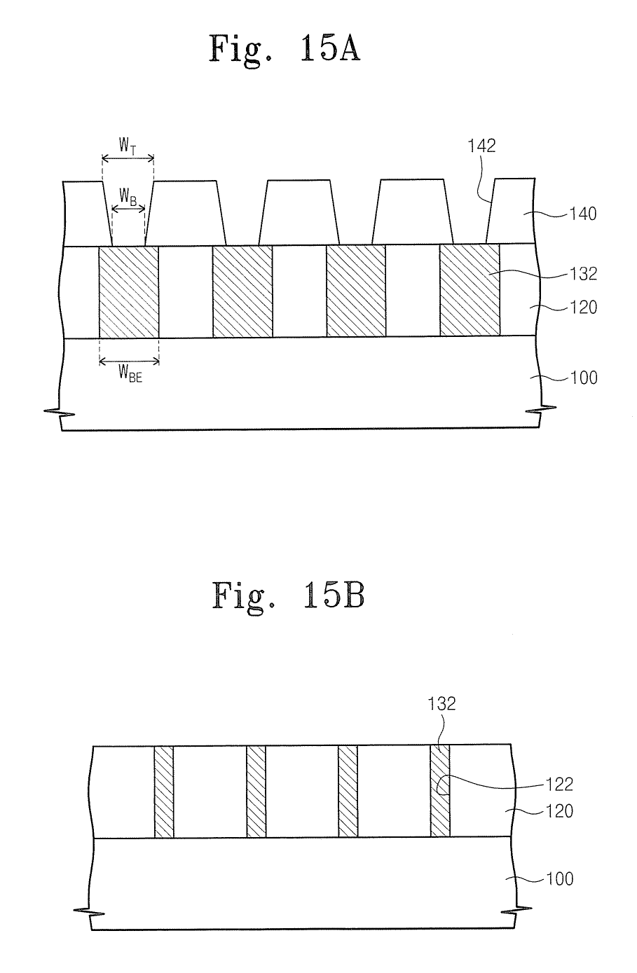

FIGS. 11A and 11B are cross sectional views of a modified embodiments of a variable resistance memory device according to some embodiments of the present invention, the cross sectional views being taken along the line A-A′ of FIG. 9A.

Referring to FIG. 11A, a lower electrode 136a may have a substantially L-shaped cross section. The lower electrode 136a may correspond to the cylindrical lower electrode 136 depicted in FIG. 10A with a portion removed. Referring to FIG. 11B, a lower electrode 136b may have a cylinder shape having an asymmetrical side portion. In particular, the lower electrode 136b may correspond to the lower electrode 136 depicted in FIG. 10A with a portion removed to reduce an area of a top surface of the lower electrode 136b in contact with the variable resistance material pattern 152. The lower electrode 136b may have a generally J-shaped cross section.

As depicted in FIGS. 11A and 11B, lower electrodes 136a and 136b may provided a reduced area in contact with the variable resistance material pattern 152 compared with the lower electrode 136 shown in FIG. 10A. Because a volume of the variable resistance region 154 can be reduced, the amount of a current used when data is programmed can be reduced, thereby reducing power consumption.

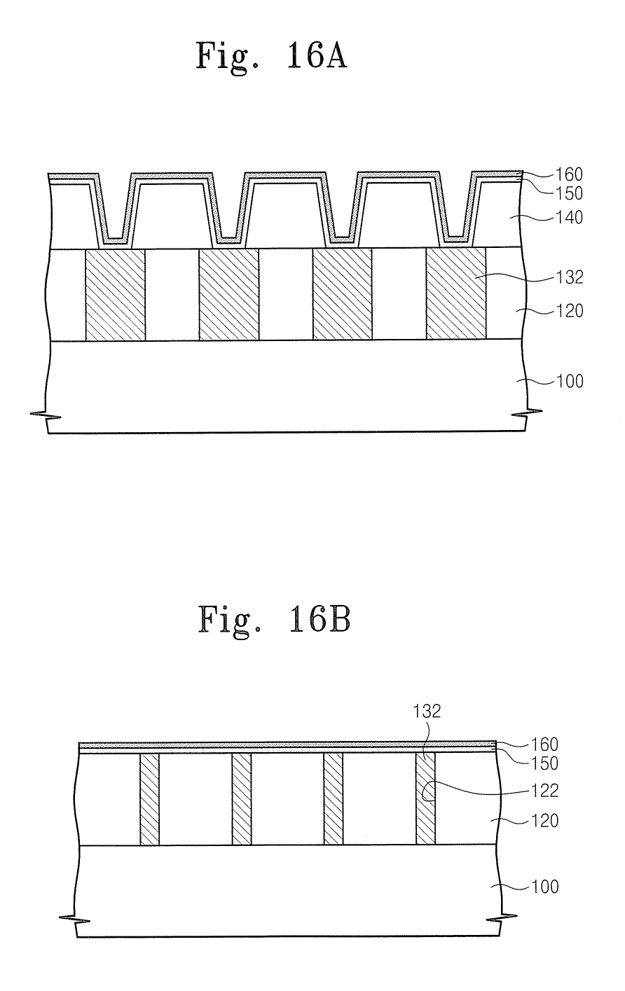

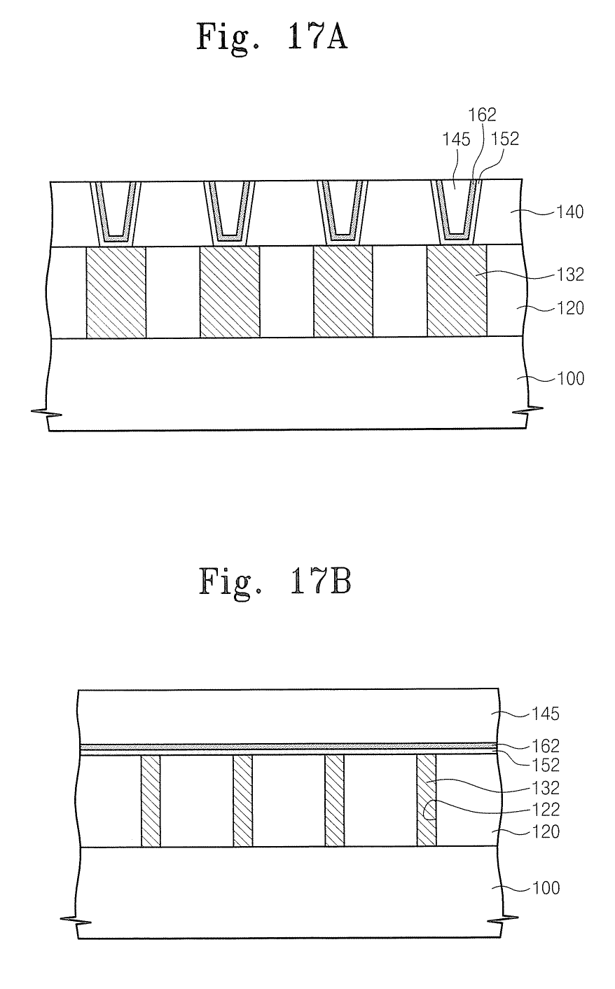

FIGS. 12A and 12B illustrate a variable resistance memory device according to further embodiments of the present invention. FIG. 12A is a top plan view of a variable resistance memory device according to some embodiments of the present invention. FIG. 12B is a top plan view of a unit memory cell region of FIG. 12A.

Referring to FIGS. 12A and 12B, lower electrodes 138 having arc-shaped top surfaces are formed in the first interlayer insulating layer 120. The lower electrodes 138 are arranged in a matrix on upper portions of the word lines 110. The lower electrodes 138 may be symmetrical to an adjacent memory cell. For example, the lower electrodes 138 may be formed by patterning a conductive layer for a lower electrode to remove the conductive layer for a lower electrode between the two memory cell regions after forming an opening across two adjacent memory cell regions and conformally depositing the conductive layer for a lower electrode along an inner wall of the opening. The lower electrodes 138 may be formed to have a C shape instead of the arc shape.

A variable resistance material pattern 152 having a generally U-shaped cross section and crossing top surfaces of the lower electrode 138 is disposed on a lower electrode 138. The variable resistance material pattern 152 may, as depicted in FIG. 4C, include a bottom member 152a and sidewalls 152b. A width of the bottom member 152a may be smaller than a distance between the sidewalls 152b. All or some of the bottom member 152a of the variable resistance material pattern 152 may be in contact with a top surface of the lower electrode 132. A width of the bottom member 152a of the variable resistance material pattern 152 may be less than, equal to or greater than a width of the lower electrode 138.

The configuration of the lower electrode 138 may be advantageous for purposes of manufacturing because it can reduce the complexity of a patterning process when forming the lower electrode 138. A contact area between the lower electrode 138 and the variable resistance material pattern 152 may also be reduced. In FIG. 12B, hatching represents the arc-shaped contact area between the lower electrode 138 and the variable resistance material pattern 152. The lower electrode 138 may, along lines described above with reference to FIGS. 5A through 6B, protrude from or be recessed with respect to the first interlayer insulating layer 120.

A heat loss preventing layer 162 is formed along an inner wall of the variable resistance material pattern 152. An insulating layer 145 is disposed between sidewalls of the variable resistance material pattern 152, on the heat loss preventing layer 162. An upper electrode 175 is disposed on a top surface of the variable resistance material pattern 152. The upper electrode 175 may have a plate shape or a line shape perpendicular to the word line 110. The upper electrode 175 may be used as a bit line (BL) contact. Bit lines 195 crossing the word lines 110 are disposed on the upper electrodes 175. The bit lines 195 can be electrically connected to the upper electrodes 175 through contact plugs 185.

A cross section structure of a variable resistance memory device including the lower electrode 138 having an arc shape may, as depicted in FIGS. 4A and 4B, be similar to a cross section structure of a variable resistance memory device including the lower electrode 138 having a line shape.

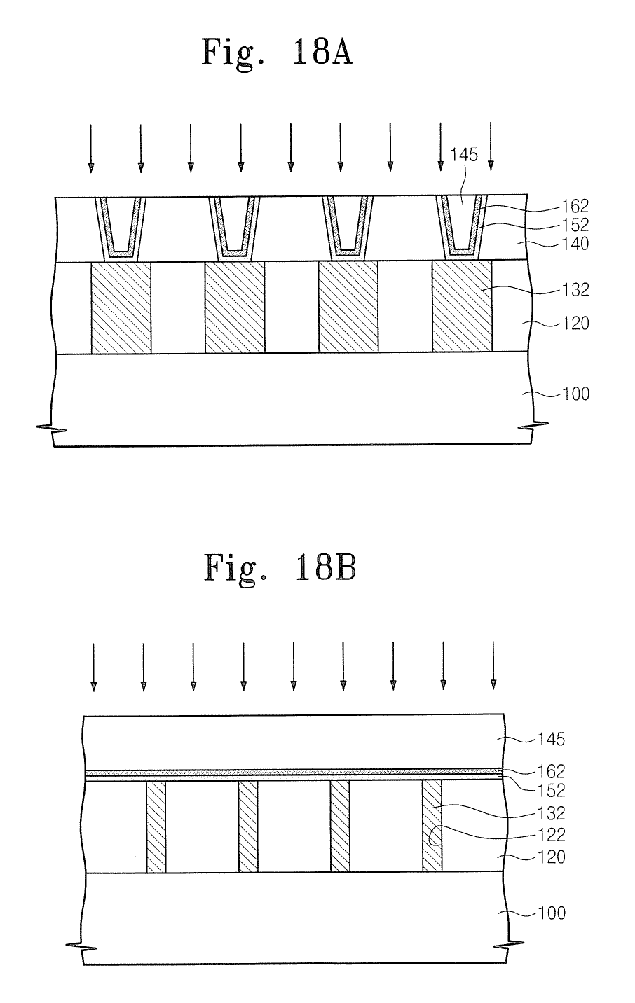

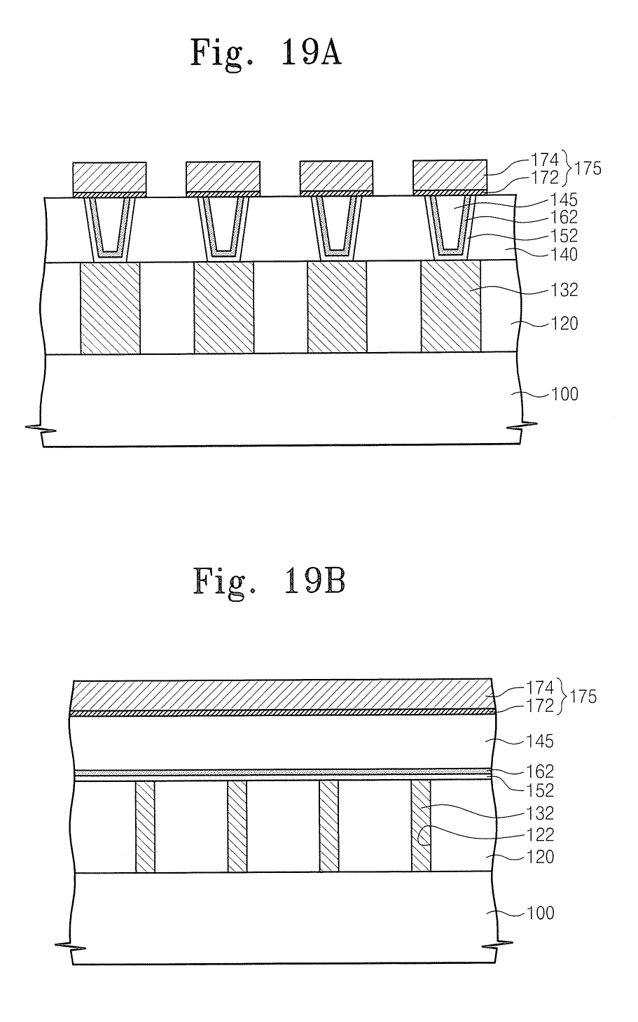

Hereinafter, operations for manufacturing variable resistance memory devices according to some embodiments of the present invention will be described in detail. FIGS. 13A through 19A and 13B-19B are cross sectional views illustrating operations for manufacturing a variable resistance memory device according to some embodiments of the present invention, the cross sectional views being taken along the lines A-A′ and B-B, respectively, of FIG. 3A.

Referring to FIGS. 3A, 13A and 13B, a semiconductor substrate 100 including word lines 110 and selection devices (not shown) is provided. The word lines 110 have a line shape and may be an impurity regions doped with an impurity. A device isolation layer (not shown) may be formed between the word lines 110. Selection devices, such as diodes or transistors, are formed on the word lines 110.

A first interlayer insulating layer 120 is formed on the semiconductor substrate 100, and trenches 122 for forming a lower electrode are formed in the first interlayer insulating layer 120. The trenches 122 may expose the semiconductor substrate 100 and may extend in one direction, e.g., a direction parallel to the word lines 110 or a direction perpendicular to the word lines 110. The trenches 122 for the lower electrode may be formed on an upper portion of adjacent two word lines 110.

The trenches 122 may be formed in various shapes depending on a shape of the lower electrodes to be formed. A conductive layer 130 is conformally deposited along a surface of the first interlayer insulating layer 120 and in the trenches 122. A line width of the lower electrode is determined according to a deposition thickness of the conductive layer 130. That is, the lower electrode having a line width less than a line width of the word line 110 and a resolution limit may be formed. The conductive layer for the lower electrode may be formed from Ti, TiSix, TiN, TiON, TiW, TiAIN, TiAION, TiSiN, TiBN, W, WSix, WN, WON, WSiN, WBN, WCN, Ta, TaSix, TaN, TaON, TaAIN, TaSIN, TaCN, Mo, MoN, MoSiN, MoAIN, NbN, ZrAIN, Ru, CoSix, NiSix, a conductive carbon group, Cu and combinations thereof.

Referring to FIGS. 3A, 14A and 14B, the conductive layer 130 for the lower electrode is patterned to form a lower conductive 132 having a straight shape in the first interlayer insulating layer 120.

In detail, after the conductive layer 130 is conformally formed in the trenches 122, the conductive layer 130 is anisotropically etched to form lower electrode patterns on sidewalls of the trenches 122. The lower electrode patterns may have a line shape. For example, the lower electrode patterns may be formed to cross a plurality of word lines 110 or to be parallel to the word lines 110.

The trenches 122 are filled with an insulating layer and the insulating layer is planarized to the top surface of the lower electrode patterns. After filling the trenches 122 with the insulating layer, a mask pattern (not shown) is formed and the lower electrode patterns are patterned to form the lower electrodes 132. In particular, portions of the lower electrode patterns are removed at predetermined intervals to form a plurality of lower electrodes 132 having top surfaces of a straight shape. The lower electrodes 132 may extend in the first direction or the second direction and the lower electrodes 132 may be disposed on one word line 110 at predetermined intervals.

In FIGS. 13A through 14B, an embodiment of the present invention describes forming the lower electrode 132 having a straight shape. However, it is possible to form the lower electrode having various shapes such as a square shape, a round shape, a ring shape and an arc shape in the present invention. For example, holes for lower electrodes may be formed in a first interlayer insulating layer 120 on a semiconductor substrate 100 and the hole filled with a conductive material to form lower electrodes having a pillar shape with a square or round cross section. A conductive layer for lower electrodes may be formed on inner walls of the holes and the hole filled with an insulating material to form a lower electrode having a ring shape.

A protection layer or an etch stop layer (not shown) may be formed on the lower electrodes 132. For example, the protection layer (not shown) may be formed of SiN or SiON. When forming a trench 142 for forming a variable resistance material pattern, the protection (not shown) can protect the lower electrode 132.

Referring to FIGS. 15A and 15B, a second interlayer insulating layer 140 is formed on the first interlayer insulating layer 120 and the lower electrodes 132. The second interlayer insulating layer 140 is patterned to form trenches 142 for forming variable resistance material patterns. The second interlayer insulating layer 140 may be, for example, a silicon oxide layer, such as borosilicate glass (BSG), phosphosilicate glass (PSG), borophosphosilicate glass (BPSG), plasma enhanced tetra ethyl ortho silicate (PE-TEOS) or high density plasma (HDP) layer.

The trenches 142 have a line shape and are formed so as to expose the lower electrodes 132. The trenches 142 may extend in the first direction or the second direction to be parallel to or perpendicular to the underlying word line 110. The trenches 142 may expose top surfaces of the lower electrodes 132 having a straight shape disposed on the same row or the same column. The trench 142 may extend in a direction perpendicular to a direction of a major axis of the lower electrodes 132.

When forming the trenches 142, the second interlayer insulating layer 140 may be anisotropically etched so that the trenches 142 have a gradually narrowing profile as the trench 142 approaches the lower electrodes 132. Thus, the trenches 142 may be formed so that a width W_{T} of upper portions of the trenches 142 is greater than a width W_{B} of lower portions of the trenches 142. A width W_{B} of a lower portion of the trenches 142 may be less than a width W_{BE} of a major axis of the lower electrodes 132. Portions of the top surfaces of the lower electrodes 132 may be exposed by the trenches 142.

Referring to FIGS. 16A and 16B, a variable resistance material layer 150 is conformally deposited along a surface of the second interlayer insulating layer 140, including in the trenches 142. The variable resistance material layer 150 may be deposited to a thickness of about 1 nm to about 50 nm, for example, a thickness of about 3 nm to about 15 nm. A phase change material layer, such as s chalcogenide material layer, may be used as the variable resistance material layer 150. For example, the variable resistance material layer 150 may be formed of two or more compounds from a group including Te, Se, Ge, Sb, Bi, Pb, Sn, Ag, As, S, Si, P, O and C. An interface layer (not shown) may be interposed between the variable resistance material layer 150 and the lower electrodes 132.

The variable resistance material layer 150 may be deposited using, for example, a physical vapor deposition (PVD) method or a chemical vapor deposition (CVD) method. The variable resistance material layer 150 deposited in the trenches 142 may have a uniform thickness and a thickness of the variable resistance material layer 150 deposited on sidewalls of the trenches 142 may be less than a thickness of the variable resistance material layer 150 deposited on bottom surfaces of the trenches 142 in contact with the lower electrode 132. The variable resistance material layer 150 is formed along a surface of the trenches 142 to prevent a generation of voids due to poor step coverage.

A heat loss preventing layer 160 is formed on the variable resistance material layer 150. The heat loss preventing layer 160 may be relatively thin. The heat loss preventing layer 160 may be formed on the variable resistance material layer 150 so as fully or partially fill the trenches 142. The heat loss preventing layer 160 may be formed, for example, from SiN, PE-SiN, SiON, C, ALD-AIN, GeN, Al₂O₃, MgO, SiO₂, CaO, Y₂O₃, TiO₂, Cr₂O₃, FeO, CoO, ZrO and/or CuO₂.

The heat loss preventing layer 160 may prevent heat dissipation when a variable resistance material is heated by the lower electrode 132. Also, the heat loss preventing layer 160 may function as an etching stop layer when a subsequent process is performed to divide the variable resistance material layer 150 into variable resistance material patterns. In particular, the heat loss preventing layer 160 may protect the variable resistance material layer 150 from a subsequent process.

Referring to FIGS. 17A and 17B, an insulating layer 145 is formed on the heat loss preventing layer 160 to fill the trenches 142. The insulating layer 145 may comprise a material having a superior gap-filling characteristic, for example, high density plasma (HDP) oxide, plasma-enhanced tetraethylorthosilicate (PE-TEOS), borophosphosilicate glass (BPSG), undoped silicate glass (USG), flowable oxide (FOX) or hydrosilsesquioxane (HSO). In some embodiments, spin on glass (SOG), such as tonensilazene (TOSZ), may be used as the insulating layer 145.

After the trench 142 is filled with the insulating layer 145, a planarization process is performed to divide the variable resistance material layer 150 into variable resistance material patterns 152. A chemical mechanical polishing (CMP) process or an etch-back process may be used as for the planarization process. The heat loss preventing layer 160 may function as an etching stop layer in the planarization.

The planarization leaves variable resistance material patterns 152 with a U-shaped cross section in the trenches 142. Top surfaces of the second interlayer insulating layer 140, the variable resistance material pattern 152, the heat loss preventing layer 162 and the insulating layer pattern 145 may be coplanar.

Referring to FIGS. 18A and 18B, a plasma treatment using an inert gas may subsequently be performed. The plasma treatment may remove surface damage on the variable resistance material patterns caused by the planarization process or a surface contaminant. For example, RF power may be applied to an inert gas to generate plasma and the plasma reacted at the surfaces of the variable resistance material patterns. As a result, damage to the surfaces of the variable resistance patterns may be removed. Ar, He, Ne, Kr or Xe may be used as an inert gas.

Referring to FIGS. 19A and 19B, upper electrodes 175 are formed on the variable resistance material patterns 152. A conductive layer 174 for an upper electrode is formed on the second interlayer insulating layer 140 including the variable resistance material patterns 152. For example, the upper electrode conductive layer 174 may be a Ti layer, TiSix layer, TiN layer, TiON layer, TiW layer, TiAIN layer, TiAION layer, TiSiN layer, TiBN layer, W layer, WSix layer, WN layer, WON layer, WSiN layer, WBN layer, WCN layer, Ta layer, TaSix layer, TaN layer, TaON layer, TaAIN layer, TaSIN layer, TaCN layer, Mo layer, MoN layer, MoSiN layer, MoAIN layer, NbN layer, ZrAIN layer, Ru layer, CoSix layer, NiSix layer, conductive carbon group layer, Cu layer or combination thereof.

Before forming the conductive layer 174, a barrier layer 172 for preventing material from being diffused between the variable resistance material patterns 152 and the upper electrodes 175 may be formed. The barrier layer 172 may include, for example, Ti, Ta, Mo, Hf, Zr, Cr, W, Nb, V, N, C, Al, B, P, O and/or S. For example, the barrier layer 172 may include TiN, TiW, TiCN, TiAIN, TiSiC, TaN, TaSiN, WN, MoN and/or CN.

Subsequently, the barrier layer 172 and the conductive layer 174 are patterned to form the upper electrodes 175 on the variable resistance material patterns 152. As shown, the upper electrodes 175 may have a flat shape and may be formed on upper portions of the lower electrodes 132. The upper electrodes 175 may have a line shape extending in a second direction perpendicular to a direction of the word line 110. If the upper electrodes 175 are line shaped, the upper electrodes 175 may be used as bit lines. After the upper electrodes 175 are formed, contact plugs 185 are formed on the upper electrodes 175. Bit lines 195 extending in a direction perpendicular to the word lines 110 of FIG. 3A) may be formed on the contact plugs 185.

As depicted in FIGS. 4A and 4B, a third interlayer insulating layer 180 is formed on the second interlayer insulating layer 140. The third interlayer insulating layer 180 is patterned to form contact holes exposing the upper electrodes 175. After the contact holes are filled with a conductive material to form the contact plugs 185, the bit lines 195 are formed on the third insulating layer 180. The bit lines 195 may be perpendicular to the word lines 110.

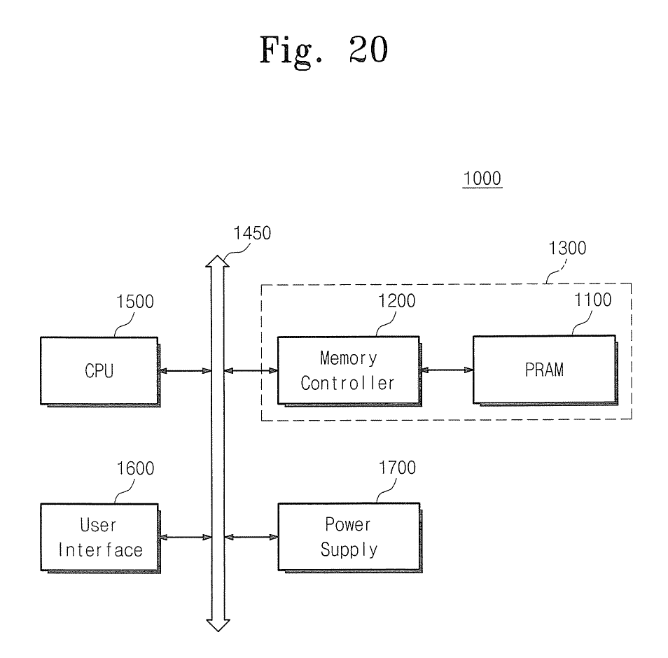

FIG. 20 is a block diagram of a memory system illustrating an application example of a variable resistance memory device according to some embodiments of the present invention. Referring to FIG. 20, a memory system 1000 according to some embodiments of the present invention includes a semiconductor memory device 1300 including a variable resistance memory device, e.g., a PRAM 1100, and a memory controller 1200. The system 100 further includes a central processing unit (CPU) 1500, a user interface 1600 and a power supply 1700.

Data provided through the user interface 1600 or generated by the central processing unit (CPU) 1500 is stored in the variable resistance memory device 1100 through the memory controller 1200. The variable resistance memory device 1100 may include a solid state drive. In this case, a writing speed of the memory system 1000 may be relatively dramatically fast. Even though not depicted in a view, it is apparent to those skilled in the art that an application chipset, a camera image processor (CIS), and a mobile DRAM may be further provided to the memory system 1000 according to the present invention. Also, the memory system 1000 can be applied to a personal digital assistant (PDA), a portable computer, a web tablet, a wireless phone, a mobile phone, a digital music player, a memory card or devices which can transmit and/or receive data under a wireless environment.

The variable resistance memory device or the memory system according to the present invention may be mounted in the shapes of a variety of packages. For example, the variable resistance memory device or the memory system according to the present invention may be packaged in the shapes of package on package (PoP), ball grid arrays (BGA), chip scale package (CSP), plastic leaded chip carrier (PLLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline (SOIC), shrink small outline package (SSQP), thin small outline (TSOP), thin quad flatpack (TQFP), system in package (SIP), multi chip package (MCP), wafer-level fabricated package (WFP), or wafer-level processed stack package (WSP).

The foregoing is illustrative of the present invention and is not to be construed as limiting thereof. Although a few embodiments of the present invention have been described, those skilled in the art will readily appreciate that many modifications are possible in the embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

1. A variable resistance memory device comprising:
a substrate;
a plurality of spaced apart lower electrodes on the substrate;
a variable resistance material pattern comprising two vertically opposed wall members connected by a bottom member disposed on and electrically connected to at least one of the plurality of lower electrodes; and
an upper electrode on the variable resistance material pattern.

2. The variable resistance memory device of claim 1, wherein the variable resistance material pattern extends linearly.

3. The variable resistance memory device of claim 1, further comprising a heat loss preventing layer conforming to an inner surface of the variable resistance material pattern.

4. The variable resistance memory device of claim 3, wherein the heat loss preventing layer comprises SiN, PE-SiN, SiON, C, ALD-AIN, GeN, Al₂O₃, MgO, SiO₂, CaO, Y₂O₃, TiO₂, Cr₂O₃, FeO, CoO, ZrO and/or CuO₂.

5. The variable resistance memory device of claim 1, wherein a width of the bottom member is less than a distance between upper edges of the wall members.

6. The variable resistance memory device of claim 1, wherein a thickness of the bottom member is greater than or equal to a thickness of the wall members.

7. The variable resistance memory device of claim 1, wherein an area of contact of the variable resistance material pattern with the at least one lower electrode is rectangular, circular, ring-shaped, or arc-shaped.

8. The variable resistance memory device of claim 7, wherein the area of contact is rectangular and wherein the variable resistance material pattern extends perpendicular to a major axis of the area of contact.

9. The variable resistance memory device of claim 1, wherein the variable resistance material pattern overlaps a sidewall surface of the at least one lower electrode.

10. The variable resistance memory device of claim 1, wherein the lower electrodes are disposed in an insulation layer, and wherein the variable resistance material pattern protrudes into the insulating layer to contact the at least one lower electrode.

11. The variable resistance memory device of claim 1, wherein the upper electrode extends parallel to the variable resistance material pattern.

12. The variable resistance memory device of claim 11, wherein the upper electrode contacts upper surfaces of the wall members of the variable resistance material pattern.

13.-20. (canceled)
